(19) United States
(12) Patent Application Publication
(10) Pub. No.: US 2026/0096331 A1
(43) Pub. Date: Apr. 2, 2026

(54) DISPLAY PANEL, DISPLAY DEVICE, AND PREPARATION METHOD FOR DISPLAY PANEL

(71) Applicant: Hefei Visionox Technology Co., Ltd., Hefei (CN)

(72) Inventors: Wenlong WANG, Hefei (CN); Zhen FU, Hefei (CN); Pei WU, Hefei (CN); Quan LEI, Hefei (CN)

(73) Assignee: Hefei Visionox Technology Co., Ltd., Hefei (CN)

(21) Appl. No.: 19/299,246

(22) Filed: Aug. 13, 2025

(30) Foreign Application Priority Data
Sep. 27, 2024 (CN) 202411369164.1

(51) Int. Cl. H10K 59/80; H10K 59/12; H10K 59/122; H10K 59/131; H10K 71/40

(52) U.S. Cl. CPC H10K 59/873; H10K 59/1201; H10K 59/122; H10K 59/131; H10K 59/80515; H10K 71/40

(57) ABSTRACT

A display panel includes a substrate, a first planarization layer, an isolation structure, a light-emitting device layer, an encapsulation layer and an isolation member, where the isolation structure is located on a side of the first planarization layer away from the substrate, and the isolation structure has a plurality of isolation openings located in an active area and at least one first opening located in a non-active area; the light-emitting device layer includes a plurality of light-emitting units located in the active area; the encapsulation layer is located on a side of the isolation structure away from the substrate; and the isolation member is located in the non-active area and separates the first planarization layer from the encapsulation layer, an orthographic projection of the isolation member on the substrate at least partially overlapping with an orthographic projection of the first opening on the substrate.

### CROSS-REFERENCE TO RELATED APPLICATIONS

The present application claims priority to Chinese Patent Application No. 202411369164.1, entitled “DISPLAY PANEL, DISPLAY DEVICE, AND PREPARATION METHOD FOR DISPLAY PANEL” and filed on Sep. 27, 2024, which is incorporated herein by reference in its entirety.

### FIELD

The disclosure relates to the field of display devices, and particularly to a display panel, a display device, a preparation method for the display panel.

### BACKGROUND

Organic light-emitting diodes (OLED) and display panels based on technologies such as light-emitting diodes (LEDs) have been widely applied in various consumer electronics, such as mobile phones, televisions, laptop computers and desktop computers, due to their advantages such as high image quality, energy efficiency, slim design and wide application ranges, and have become the mainstream in display devices. During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of traditional OLED processes on the size, resolution, and other screen performances of a display screen, and has the advantages of high performance, full-range size, and agile delivery. Reference can be made to relevant contents of the fine metal mask-free technology recited in Chinese patents CN 118251982 A, CN 116648095 A, CN 117062489 A, CN 118742138 A, CN 118678783 A, CN 118660598 A, CN 118675450 A, CN 118824188 A, CN 118781966 A.

During the process of preparing a display panel, a partial region of the display panel is likely to absorb a liquid agent used in the preparation process, and this part of the liquid agent can enter a light-emitting unit of the display panel through an encapsulation layer of the display panel, resulting in a reduced service life and display abnormalities of the light-emitting units.

### SUMMARY

Embodiments of the disclosure provide a display panel, a display device and a preparation method for the display panel, intended to optimize the problems of the reduced service life and display abnormalities of light-emitting units due to the fact that the display panel absorbs an agent used in the preparation process.

An embodiment of a first aspect of the disclosure provides a display panel having an active area and a non-active area, the non-active area being arranged around at least part of the active area, the display panel including:
a substrate;
a first planarization layer arranged on one side of the substrate;
an isolation structure located on a side of the first planarization layer away from the substrate, the isolation structure having a plurality of isolation openings located in the active area and at least one first opening located in the non-active area, at least part of an orthographic projection of the first opening on the substrate being located within an orthographic projection of the first planarization layer on the substrate;
a light-emitting device layer including a plurality of light-emitting units located in the active area, at least part of the light-emitting unit being arranged in the isolation opening, and the light-emitting unit including an organic electroluminescent material;
an encapsulation layer located on a side of the isolation structure away from the substrate and covering at least part of the first opening; and
an isolation member located in the non-active area and separating the first planarization layer from the encapsulation layer, an orthographic projection of the isolation member on the substrate at least partially overlapping with the orthographic projection of the first opening on the substrate.

According to implementations of the first aspect of the disclosure, the isolation member includes an inorganic material.

According to any one of the above implementations of the first aspect of the disclosure, the display panel further includes a first electrode layer, the first electrode layer including a plurality of first electrodes and at least one isolation electrode, the first electrode being arranged on a side of the light-emitting unit close to the substrate, an orthographic projection of the first electrode on the substrate at least partially overlapping with an orthographic projection of the isolation opening on the substrate, and the isolation electrode doubling as the isolation member.

According to any one of the above implementations of the first aspect of the disclosure, the display panel further includes a pixel defining layer arranged between the substrate and the isolation structure, the pixel defining layer including a pixel opening and a second opening, the pixel opening is in communication with the isolation opening, the light-emitting unit is at least partially arranged in the pixel opening, and the second opening is in communication with the first opening.

According to any one of the above implementations of the first aspect of the disclosure, an orthographic projection of the second opening on the substrate is located within the orthographic projection of the first opening on the substrate.

According to any one of the above implementations of the first aspect of the disclosure, the isolation member includes a first surface and a second surface arranged opposite to each other, and a side surface connected to the first surface, the first surface being arranged on a side of the second surface away from the substrate, and the pixel defining layer clads at least part of the side surface.

According to any one of the above implementations of the first aspect of the disclosure, the pixel defining layer covers part of the first surface.

According to any one of the above implementations of the first aspect of the disclosure, the plurality of first electrodes and the at least one isolation electrode are spaced apart from each other.

According to any one of the above implementations of the first aspect of the disclosure, part of the pixel defining layer is located between an adjacent one of the first electrodes and the isolation electrode.

According to any one of the above implementations of the first aspect of the disclosure, the pixel defining layer surrounds the isolation electrode.

According to any one of the above implementations of the first aspect of the disclosure, the at least one isolation electrode is connected to the first electrode.

According to any one of the above implementations of the first aspect of the disclosure, the first electrode includes a third surface in contact with the light-emitting unit, the pixel defining layer covers part of the third surface, and the first surface and the third surface are connected to form a flat surface.

According to any one of the above implementations of the first aspect of the disclosure, the display panel further includes a touch layer located on a side of the encapsulation layer away from the substrate, the touch layer including a plurality of touch units, an orthographic projection of the touch unit on the substrate at least partially overlapping with the orthographic projection of the isolation member on the substrate.

According to any one of the above implementations of the first aspect of the disclosure, the substrate includes a base substrate and a drive circuit layer arranged between the base substrate and the light-emitting device layer, the drive circuit layer including a plurality of conductive structures, an orthographic projection of part of the conductive structure on the substrate at least partially overlapping with the orthographic projection of the isolation member on the substrate.

According to any one of the above implementations of the first aspect of the disclosure, the isolation electrode is insulated from the drive circuit layer, and the first electrode is electrically connected to the drive circuit layer.

According to any one of the above implementations of the first aspect of the disclosure, part of the encapsulation layer fills the first opening and is in contact with a surface of the isolation member away from the substrate.

According to any one of the above implementations of the first aspect of the disclosure, the encapsulation layer includes a first encapsulation sublayer covering a side of the light-emitting device layer away from the substrate and the side of the isolation structure away from the substrate, part of the first encapsulation sublayer filling the first opening and being in contact with the surface of the isolation member away from the substrate.

According to any one of the above implementations of the first aspect of the disclosure, the encapsulation layer further includes a second encapsulation sublayer arranged in the active area, the second encapsulation sublayer being located between the first encapsulation sublayer and the light-emitting unit.

According to any one of the above implementations of the first aspect of the disclosure, the second encapsulation sublayer includes a plurality of encapsulation portions spaced apart from each other, an orthographic projection of the encapsulation portion on the substrate covering an orthographic projection of the light-emitting unit on the substrate.

According to any one of the above implementations of the first aspect of the disclosure, the first encapsulation sublayer is an organic encapsulation layer, and the first planarization layer is an organic encapsulation layer.

According to any one of the above implementations of the first aspect of the disclosure, the second encapsulation sublayer is an inorganic material layer.

According to any one of the above implementations of the first aspect of the disclosure, the display panel further includes a first conductive layer including a first signal line located in the non-active area, the first planarization layer has at least one third opening, and part of the isolation structure is located in the third opening and electrically connected to the first signal line.

According to any one of the above implementations of the first aspect of the disclosure, the orthographic projection of the isolation member on the substrate is located within an orthographic projection of the first signal line on the substrate.

According to any one of the above implementations of the first aspect of the disclosure, an orthographic projection of the third opening on the substrate is spaced apart from the orthographic projection of the first opening on the substrate.

According to any one of the above implementations of the first aspect of the disclosure, the display panel further includes a second planarization layer located on a side of the first conductive layer close to the substrate.

According to any one of the above implementations of the first aspect of the disclosure, the first conductive layer further includes at least one fourth opening extending through the first signal line, and the first planarization layer is in contact with the second planarization layer via the fourth opening.

According to any one of the above implementations of the first aspect of the disclosure, the orthographic projection of the first opening on the substrate is spaced apart from an orthographic projection of the fourth opening on the substrate.

According to any one of the above implementations of the first aspect of the disclosure, orthographic projections of a plurality of first openings on the substrate and orthographic projections of a plurality of third openings on the substrate are alternately spaced apart from each other in a first direction; and the orthographic projections of the plurality of third openings on the substrate and a plurality of fourth openings are alternately spaced apart from each other in the first direction.

According to any one of the above implementations of the first aspect of the disclosure, the display panel further includes a second electrode layer, the second electrode layer including a plurality of second electrodes arranged on a side of the light-emitting unit away from the substrate, the second electrode being in lap joint with the isolation structure, and the second electrode being electrically connected to the isolation structure.

According to any one of the above implementations of the first aspect of the disclosure, the isolation structure includes a first isolation layer and a second isolation layer arranged in a stacked manner, the first isolation layer being arranged on a side of the second isolation layer close to the substrate, and an orthographic projection of the first isolation layer on the substrate being located within an orthographic projection of the second isolation layer on the substrate.

According to any one of the above implementations of the first aspect of the disclosure, the orthographic projection of the isolation member on the substrate at least partially overlaps with an orthographic projection of the isolation structure on the substrate.

According to any one of the above implementations of the first aspect of the disclosure, an orthographic projection of the first isolation layer on the substrate surrounds and overlaps with the orthographic projection of the isolation member on the substrate.

According to any one of the above implementations of the first aspect of the disclosure, an area of an orthographic projection of a surface, away from the substrate, of the second isolation layer on the substrate is less than an area of an orthographic projection of a surface, close to the substrate, of the second isolation layer on the substrate.

According to any one of the above implementations of the first aspect of the disclosure, an area of an orthographic projection of a surface, away from the substrate, of the first isolation layer on the substrate is less than an area of an orthographic projection of a surface, close to the substrate, of the second isolation layer on the substrate.

According to any one of the above implementations of the first aspect of the disclosure, the display panel further includes a second electrode layer located in the active area, the second electrode layer including a plurality of second electrodes arranged on a side of the light-emitting unit away from the substrate, the second electrode being in lap joint with and electrically connected to the first isolation layer.

According to any one of the above implementations of the first aspect of the disclosure, the isolation structure further includes a third isolation layer arranged on a side of the first isolation layer close to the substrate, the orthographic projection of the first isolation layer on the substrate being located within an orthographic projection of the third isolation layer on the substrate.

According to any one of the above implementations of the first aspect of the disclosure, the display panel further includes a pixel defining layer arranged between the first planarization layer and the isolation structure, the pixel defining layer including a pixel opening, the pixel opening is in communication with the isolation opening, the light-emitting unit is at least partially arranged in the pixel opening, and part of the pixel defining layer doubles as the isolation member.

An embodiment of a second aspect of the disclosure provides a display panel having an active area and a non-active area, the non-active area being arranged around at least part of the active area, the display panel including:
a substrate;
a first planarization layer arranged on one side of the substrate;
a pixel defining layer located on a side of the first planarization layer away from the substrate, the pixel defining layer including a plurality of pixel openings located in the active area and at least one second opening located in the non-active area, at least part of an orthographic projection of the second opening on the substrate being located within an orthographic projection of the first planarization layer on the substrate;
a light-emitting device layer including a plurality of light-emitting units located in the active area, at least part of the light-emitting unit being arranged in the pixel opening, and the light-emitting unit including an organic electroluminescent material;
an encapsulation layer located on a side of the pixel defining layer away from the substrate and covering at least part of the second opening; and
an isolation member located in the non-active area and separating the first planarization layer from the encapsulation layer, an orthographic projection of the isolation member on the substrate at least partially overlapping with the orthographic projection of the second opening on the substrate.

An embodiment of a third aspect of the disclosure provides a preparation method for a display panel, the display panel having an active area and a non-active area, the non-active area being arranged around at least part of the active area, the preparation method including:
providing a substrate on which a first planarization layer is provided;
forming a first electrode layer on the first planarization layer, the first electrode layer including a plurality of first electrodes located in the active area and an isolation electrode located in the non-active area, the isolation electrode doubling as an isolation member;
forming an isolation structure on a side of the first electrode layer away from the substrate, the isolation structure having a plurality of isolation openings located in the active area and at least one first opening located in the non-active area, an orthographic projection of the first opening on the substrate at least partially overlapping with an orthographic projection of the isolation electrode on the substrate;
providing a light-emitting device layer by means of the isolation structure, the light-emitting device layer including a plurality of light-emitting units located in the active area, at least part of the light-emitting unit being arranged in the isolation opening; and
forming an encapsulation layer on a side of the isolation structure away from the substrate, and the isolation member separating the first planarization layer from the encapsulation layer.

According to implementations of the third aspect of the disclosure, after forming a first electrode layer on the first planarization layer, the preparation method includes:
performing an annealing treatment on the first electrode layer;

According to any one of the above implementations of the third aspect of the disclosure, in the annealing treatment, the annealing temperature ranges from 200° C. to 240° C. and the annealing time ranges from 30 min to 70 min.

An embodiment of a fourth aspect of the disclosure further provides a display device, including a display panel according to any one of the above embodiments of the first and second aspects or a display panel prepared by any one of the above embodiments of the third aspect.

In the display panel, the display device, and the preparation method for the display panel according to the embodiments of the disclosure, by providing the first opening in the isolation structure, water vapor in the first planarization layer can be discharged outwardly through the first opening during the preparation of the display panel; the arrangement of the first opening in the non-active area facilitates an increase in the distribution density of the light-emitting units in the active area; and by configuring the orthographic projection of the isolation member on the substrate to at least partially overlap with the orthographic projection of the first opening on the substrate and the isolation member to separate the first planarization layer from the encapsulation layer, the isolation member can isolate the first planarization layer from the encapsulation layer to avoid contact between the first planarization layer and the encapsulation layer, thereby avoiding or reducing the absorption of a liquid agent during the preparation of the first planarization layer, avoiding or reducing the water vapor in the first planarization layer entering the encapsulation layer through the first opening, prolonging the service life of the light-emitting units, and avoiding or reducing display abnormalities of the light-emitting units.

### BRIEF DESCRIPTION OF THE DRAWINGS

In order to describe the embodiments of the disclosure more clearly, the drawings required for illustration of the embodiments of the disclosure will be briefly introduced below. The drawings as described below are only for some of the embodiments of the disclosure.

FIG. 1 is a structural schematic plan view of a display panel according to some embodiments of the disclosure;

FIG. 2 is a structural schematic partial cross-sectional view of a display panel according to some embodiments of the disclosure;

FIG. 3 is a structural schematic partial cross-sectional view of a display panel according to some embodiments of the disclosure;

FIG. 4 is a structural schematic partial plan view of a display panel according to some embodiments of the disclosure;

FIG. 5 is a structural schematic partial cross-sectional view of a display panel according to some embodiments of the disclosure;

FIG. 6 is a structural schematic partial plan view of a display panel according to some embodiments of the disclosure;

FIG. 7 is a structural schematic partial cross-sectional view of a display panel according to some embodiments of the disclosure;

FIG. 8 is a structural schematic partial cross-sectional view of a display panel according to some embodiments of the disclosure;

FIG. 9 is a structural schematic partial cross-sectional view of a display panel according to some embodiments of the disclosure; and

FIG. 10 is a structural schematic partial cross-sectional view of a display panel according to some embodiments of the disclosure.

### DETAILED DESCRIPTION OF THE EMBODIMENTS

Features and exemplary embodiments in various aspects of the disclosure will be described in detail below. In order to make the embodiments of the disclosure clearer, the disclosure will be further described in detail below with reference to the accompanying drawings and embodiments. It should be understood that the embodiments described herein are merely configured to explain the disclosure and are not configured to limit the disclosure. The disclosure may be implemented without some of these details. The following description of the embodiments is merely to provide a better understanding of the disclosure by illustrating examples of the disclosure.

It should be noted that, herein, relative terms such as “first” and “second” are only used to distinguish one entity or operation from another entity or operation, and do not necessarily require or imply that such an actual relationship or order exists between these entities or operations. Moreover, the terms “include”, “comprise”, or any other variants thereof are intended to cover a non-exclusive inclusion, and a process, a method, an article, or a device that includes a list of elements not only includes those elements but also includes other elements that are not listed, or further includes elements inherent to such a process, method, article, or device. If no more limitations are made, an element limited by “comprising/including . . . ” does not exclude other identical elements existing in the process, the method, the article, or the device which includes the element.

It should be understood that in the description of the structure of a component, a layer or region referred as being located “above” or “over” another layer or region may be directly on the other layer or region, or there may be other layers or regions between it and the other layer or region. Moreover, if the component is turned over, the layer or region will be located “below” or “under” the other layer or region.

During the preparation of a display panel, water vapor is discharged from a first planarization layer through a first opening provided in an isolation structure. In subsequent processes, part of a liquid agent may enter the first planarization layer through the first opening. In the finished display panel, the water vapor in the first planarization layer may enter, through the first opening, an encapsulation layer located on one side of the isolation structure, thereby increasing the probability of water vapor entering light-emitting units through the encapsulation layer, resulting in the reduced service life and display abnormalities of the light-emitting units.

In order to solve the above problem, the embodiments of the disclosure provide a display panel, a display device and a preparation method for the display panel. Various embodiments of the display panel, the display device and the preparation method for the display panel will be illustrated below with reference to the drawings.

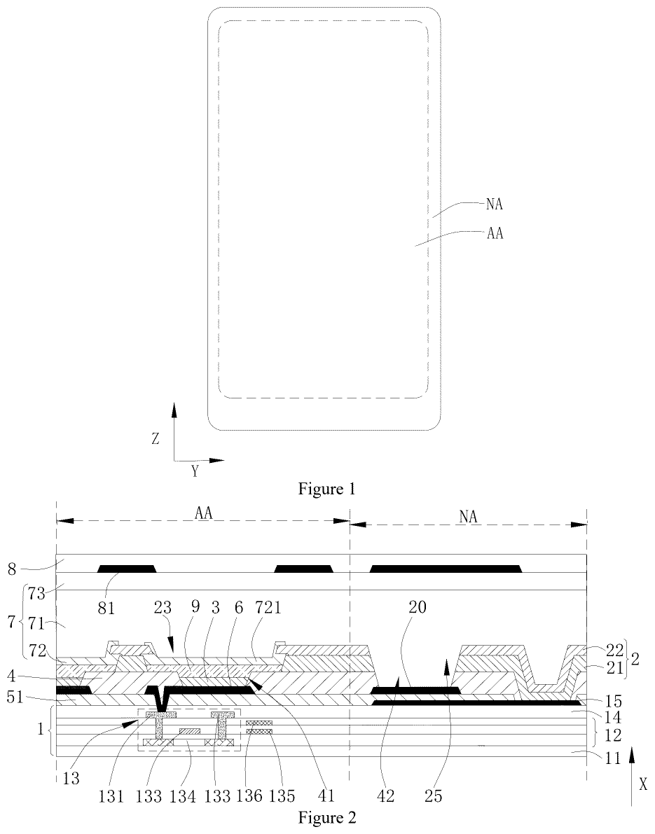

As shown in FIGS. 1 and 2, a first aspect of the disclosure provides a display panel 100. The display panel 100 has an active area AA and a non-active area NA, the non-active area NA being arranged around at least part of the active area AA. The display panel 100 includes: a substrate 1, a first planarization layer 51, an isolation structure 2, a light-emitting device layer, an encapsulation layer 7 and an isolation member 20. The first planarization layer 51 is arranged on one side of the substrate 1. The isolation structure 2 is located on a side of the first planarization layer 51 away from the substrate 1, the isolation structure 2 has a plurality of isolation openings 23 and at least one first opening 25. The isolation openings 23 are located in the active area AA, and the first opening 25 is located in the non-active area NA. At least part of an orthographic projection of the first opening 25 on the substrate 1 is located within an orthographic projection of the first planarization layer 51 on the substrate 1. The light-emitting device layer includes a plurality of light-emitting units 3 located in the active area AA. At least part of the light-emitting unit 3 is arranged in the isolation opening 23, and the light-emitting unit 3 includes an organic electroluminescent material. The encapsulation layer 7 is located on a side of the isolation structure 2 away from the substrate 1 and covers at least part of the first opening 25. The isolation member 20 is located in the non-active area NA, an orthographic projection of the isolation member 20 on the substrate 1 at least partially overlaps with the orthographic projection of the first opening 25 on the substrate 1, and the isolation member 20 separates the first planarization layer 51 from the encapsulation layer 7.

In the display panel 100 according to the embodiments of the disclosure, the display panel 100 may be a display panel 100 based on organic light-emitting diode (OLED) technology. For the isolation structure 2, reference can be made to the relevant descriptions in Chinese patents CN 118251982 A, 202410864269.8, PCT/CN 2024/098407, PCT/CN 2024/102783, PCT/CN 2024/098217, PCT/CN 2024/099419, and PCT/CN 2024/099072.

The plurality of light-emitting units 3 are arranged in the active area AA, and the active area AA can emit light for display. The non-active area NA is not used for display and light emission, and no light-emitting unit 3 may be provided in the non-active area NA. Signal lines for electrical connection with the light-emitting units 3 may be distributed in the non-active area NA, to reduce the space of the active area AA occupied by the signal lines, thereby facilitating an increase in the distribution density of the light-emitting units 3 in the active area AA.

In the display panel 100 according to the embodiments of the disclosure, the substrate 1 may not only provide a support force for the isolation structure 2, but may also provide an electrical signal for the light-emitting device layer. The substrate 1 includes a base substrate 11 and a drive circuit layer 12. The drive circuit layer 12 is arranged between the base substrate 11 and the light-emitting device layer. The drive circuit layer 12 may include a pixel drive circuit. By way of example, the pixel drive circuit arranged on the drive circuit layer 12 includes a transistor 13 and a storage capacitor. The transistor 13 includes an active layer 134, a gate 133, a drain 132, and a source 131. The storage capacitor includes a first plate 135 and a second plate 136. A plurality of patterned conductive layers form the transistor 13 and the storage capacitor.

The first planarization layer 51 may be configured to planarize a functional layer located on a side thereof close to the substrate 1. The functional layer may be a conductive layer forming the source 131 and the drain 132, or may be a conductive layer for connection with the source 131 and the drain 132 by means of via holes.

During the preparation of the display panel 100, the isolation structure 2 is located on a side of the first planarization layer 51 away from the substrate 1. At least part of the orthographic projection of the first opening 25 on the substrate 1 is located within the orthographic projection of the first planarization layer 51 on the substrate 1, the first planarization layer 51 is baked, and water vapor in the first planarization layer 51 may be discharged outwardly through the first opening 25 to keep the first planarization layer 51 dry. There may be one first opening 25, or a plurality of first openings 25 which may be spaced apart from each other.

The isolation structure 2 defines a plurality of isolation openings 23, and adjacent isolation openings 23 are separated by the isolation structure 2. The number of isolation openings 23 may correspond to the number of light-emitting units 3 on a one-to-one basis. The plurality of light-emitting units 3 may be light-emitting units 3 capable of emitting light of different colors. For example, the plurality of light-emitting units may be a red light-emitting unit capable of emitting red light, a green light-emitting unit capable of emitting green light, and a blue light-emitting unit capable of emitting blue light.

The encapsulation layer 7 may be made of an organic and/or inorganic material. The encapsulation layer 7 facilitates an improvement in ability to isolate the light-emitting device layer from water and oxygen.

The encapsulation layer 7 extends from the active area AA to the non-active area NA. The encapsulation layer 7 is located on a side of the light-emitting device layer away from the substrate 1 and covers part of or the entire first opening, thus enabling full-surface encapsulation of the active area AA and the non-active area NA. The encapsulation layer 7 in the active area AA can encapsulate the light-emitting device layer and the side of the isolation structure 2 away from the substrate 1, preventing external water and oxygen from entering the light-emitting units 3 from the light-emitting device layer and the side of the isolation structure 2 away from the substrate 1, which otherwise affects the display and light emission of the light-emitting units 3. The encapsulation layer 7 in the non-active area NA is stacked on the side of the isolation structure 2 away from the substrate 1, preventing external water and oxygen from entering the active area AA from the non-active area NA, which otherwise affects the display and light emission of the light-emitting units 3.

The orthographic projection of the isolation member 20 on the substrate 1 at least partially overlaps with the orthographic projection of the first opening 25 on the substrate 1, the isolation member 20 may be entirely arranged in the first opening 25, may be partially arranged in the first opening 25, or may be arranged outside the first opening 25. The isolation member 20 separates the first planarization layer 51 from the encapsulation layer 7, that is, the first planarization layer 51 and the encapsulation layer 7 are not in contact with each other, and the water vapor in the first planarization layer 51 cannot enter the encapsulation layer 7 through the first opening 25, nor can the water vapor in the encapsulation layer 7 enter the first planarization layer 51 through the first opening 25. Unless otherwise specified, the orthographic projection on the substrate 1 in the disclosure is a projection in a third direction X. The third direction X may be a thickness direction of the display panel 100, or a direction perpendicular to the substrate 1.

The display panel 100 provided in the disclosure may further include a cover plate located on a side of the light-emitting device layer away from the substrate 1, a touch layer 8 located between the cover plate and the light-emitting device layer, and an optical adhesive layer located between the cover plate and the touch layer 8. The cover plate protects the display panel 100 from external scratches and damage to the display panel 100. The touch layer 8 enables a touch function. The optical adhesive layer bonds the cover plate to the touch layer 8.

In the display panel 100 provided by the disclosure, by providing the first opening 25 in the isolation structure 2, the water vapor in the first planarization layer 51 can be discharged outwardly through the first opening 25 during the preparation of the display panel 100; the arrangement of the first opening 25 in the non-active area NA facilitates an increase in the distribution density of the light-emitting units 3 in the active area AA; and by configuring the orthographic projection of the isolation member 20 on the substrate 1 to at least partially overlap with the orthographic projection of the first opening 25 on the substrate 1 and the isolation member 20 to separate the first planarization layer 51 from the encapsulation layer 7, the isolation member 20 can isolate the first planarization layer 51 from the encapsulation layer 7 to avoid contact between the first planarization layer 51 and the encapsulation layer 7, thereby avoiding or reducing the absorption of a liquid agent during the preparation of the first planarization layer 51, avoiding or reducing the water vapor in the first planarization layer 51 entering the encapsulation layer 7 through the first opening 25, prolonging the service life of the light-emitting units 3, and avoiding or reducing display abnormalities of the light-emitting units 3.

In some embodiments, the isolation member 20 includes an inorganic material.

The inorganic material has a good water blocking capability. The isolation member 20 includes an inorganic material, to improve the ability of the isolation member 20 to avoid or reduce the water vapor in the first planarization layer 51 entering the encapsulation layer 7 through the first opening 25.

In some embodiments, the isolation member 20 is a conductive member and the isolation member 20 has the effect of avoiding signals. For example, the isolation member 20 may shield the mutual interference between the touch layer 8 located on the side of the isolation member away from the base substrate 11 and the drive circuit layer 12 located on the side of the isolation member close to the base substrate 11.

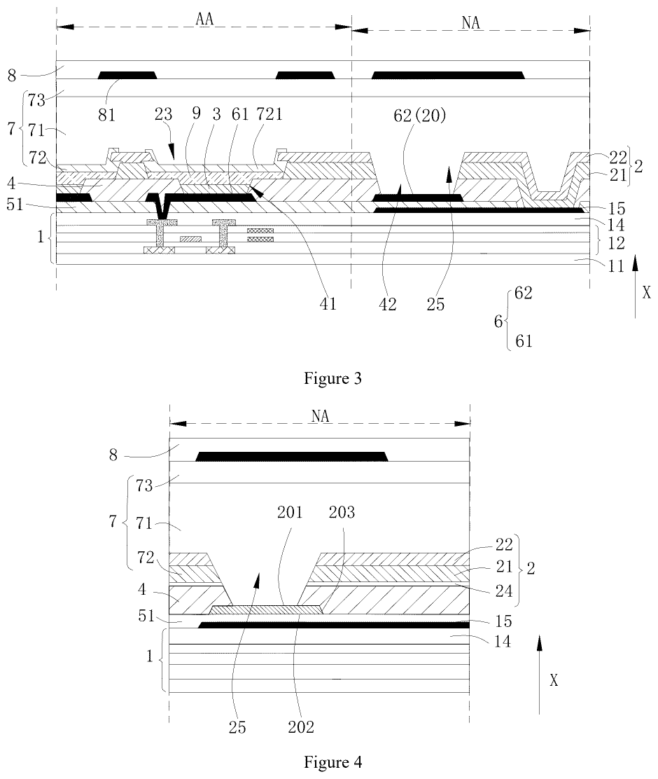

Referring to FIGS. 3 and 4, in some embodiments, the display panel 100 further includes a first electrode layer 6. The first electrode layer 6 includes a plurality of first electrodes 61 and at least one isolation electrode 62. The first electrode 61 is arranged on a side of the light-emitting unit 3 close to the substrate 1, an orthographic projection of the first electrode 61 on the substrate 1 at least partially overlaps with an orthographic projection of the isolation opening 23 on the substrate 1, and the isolation electrode 62 doubles as the isolation member 20.

An electrode material for preparing the first electrode layer 6 may be laid on one side of the entire substrate 1, and the electrode material is patterned to form a plurality of first electrodes 61 and an isolation electrode 62. The isolation electrode 62 doubles as the isolation member 20, that is, the isolation electrode 62 isolates the first planarization layer 51 from the encapsulation layer 7, the orthographic projection of the isolation electrode 62 on the substrate 1 overlaps with the orthographic projection of the first opening 25 on the substrate 1, and the isolation electrode 62 has the ability to prevent the flow of water vapor between the first planarization layer 51 and the encapsulation layer 7.

The preparation process is simplified by doubling the isolation electrode 62 as the isolation member 20, thereby eliminating the step of separately preparing the isolation member 20.

In some embodiments, the display panel 100 further includes a pixel defining layer 4. The pixel defining layer 4 is arranged between the substrate 1 and the isolation structure 2, and the pixel defining layer 4 includes a pixel opening 41 and a second opening 42. The pixel opening 41 is in communication with the isolation opening 23, the light-emitting unit 3 is at least partially arranged in the pixel opening 41, and the second opening 42 is in communication with the first opening 25.

The pixel defining layer 4 is arranged on the side of the first planarization layer 51 away from the substrate 1, and the pixel defining layer 4 includes a pixel opening 41 located in the active area AA and a second opening 42 located in the non-active area NA. The position, shape and size of the light-emitting unit 3 are defined by the pixel opening 41. The isolation structure 2 may be directly arranged on a side of the pixel defining layer 4 away from the substrate 1, and the isolation structure 2 is supported by means of the pixel defining layer 4. The isolation member 20 may be entirely located in the second opening 42, or partially located in the second opening 42, or located outside the second opening 42.

In some embodiments, an orthographic projection of the second opening 42 on the substrate 1 is located within the orthographic projection of the first opening 25 on the substrate 1.

During the preparation of the display panel, a pixel defining material layer and an isolation material layer may be provided in sequence on one side of the first planarization layer 51, and the first opening 25 and the second opening 42 are formed in sequence by an etching process. The opening size of the second opening 42 formed later is smaller than the size of the first opening 25 formed earlier, that is, the orthographic projection of the second opening 42 on the substrate 1 is located within the orthographic projection of the first opening 25 on the substrate 1.

In some embodiments, the isolation member 20 includes a first surface 201 and a second surface 202 arranged opposite to each other, and a side surface 203 connected to the first surface 201. The first surface 201 is arranged on a side of the second surface 202 away from the substrate 1, and the pixel defining layer 4 clads at least part of the side surface 203.

The isolation member 20 may be prepared first, and the pixel defining layer 4 having the second opening 42 is then prepared. The pixel defining layer 4 may cover part of the isolation member 20. For example, the pixel defining layer 4 clads at least part of the side surface 203, to reduce the contact of the side surface 203 with a preparation agent in subsequent processes, thereby avoiding or reducing damage to the side surface 203 caused by the preparation agent.

In some embodiments, the pixel defining layer 4 covers part of the first surface 201.

The pixel defining layer 4 may extend from the side surface 203 to an edge of the first surface 201, thereby ensuring that the pixel defining layer 4 efficiently clads the side surface 203.

In some embodiments, the plurality of first electrodes 61 and the at least one isolation electrode 62 are spaced apart from each other and the first electrodes 61 and the isolation electrode 62 may be respectively configured to transmit different electrical signals.

In some embodiments, part of the pixel defining layer 4 is located between an adjacent one of the first electrodes 61 and the isolation electrode 62.

The pixel defining layer 4 may be made of an insulating material, and the part of the pixel defining layer 4 being located between the adjacent first electrode 61 and the isolation electrode 62 avoids cross-talk of the electrical signals transmitted by the first electrode 61 and the isolation electrode 62.

In some embodiments, the pixel defining layer 4 surrounds the isolation electrode 62.

Peripheral sides of the isolation electrodes 62 are all surrounded by the pixel defining layer 4. In one embodiment, the edge of the first surface 201 and the side surface 203 are both covered by the pixel defining layer 4.

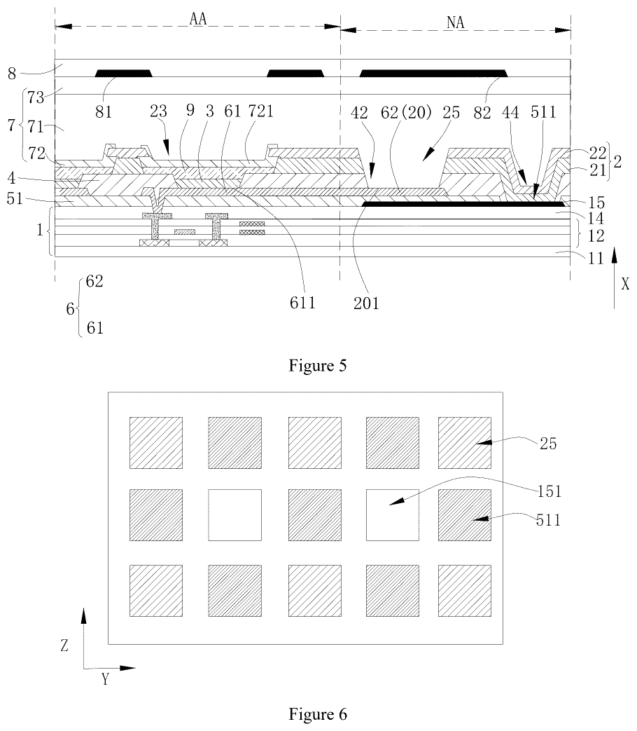

Referring to FIG. 5, in some other embodiments, at least one isolation electrode 62 is connected to the first electrode 61.

In the display panel, it is possible that some of the isolation electrodes 62 are connected to the first electrode 61, and some of the isolation electrodes 62 are spaced apart from the first electrode 61. It is also possible that all the isolation electrodes 62 are respectively connected to different first electrodes 61. The isolation electrode 62 and the first electrode 61 connected together may transmit the same electrical signal.

In some embodiments, the first electrode 61 includes a third surface 611 in contact with the light-emitting unit 3, the pixel defining layer 4 covers part of the third surface 611, and the first surface 201 and the third surface 611 are connected to form a flat surface.

The first electrode 61 and the isolation electrode 62 may be obtained by patterning the same electrode material layer, and the first electrode 61 and the isolation electrode 62 are both formed on the first planarization layer 51 and the first surface 201 and the third surface 611 are connected to form a flat surface, and the first electrode 61 and the isolation electrode 62 have the same thickness in a direction close to the substrate 1.

In some embodiments, the display panel 100 further includes a touch layer 8. The touch layer 8 is located on a side of the encapsulation layer 7 away from the substrate 1, and the touch layer 8 includes a plurality of touch units 81. An orthographic projection of the touch unit 81 on the substrate 1 at least partially overlaps with the orthographic projection of the isolation member 20 on the substrate 1.

The touch layer 8 enables a touch operation to be performed on the display panel 100. To prevent the touch layer 8 from affecting the display of the light-emitting device layer, the touch layer 8 may be made of a light transmitting material. The touch layer 8 is a self-capacitive touch layer 8 or a mutual-capacitive touch layer 8.

The mutual-capacitive touch layer 8 includes a first touch sublayer and a second touch sublayer. When a finger touches the display panel 100, a first touch unit in the first touch sublayer and a second touch unit in the second touch sublayer respectively form a coupling capacitance, and touch control is achieved by the changes in capacitance. The orthographic projection of the isolation member 20 on the substrate 1 at least partially overlaps with an orthographic projection of the first touch unit on the substrate 1, i.e., the isolation member 20 has a signal shielding effect on the first touch unit. The orthographic projection of the isolation member 20 on the substrate 1 at least partially overlaps with an orthographic projection of the second touch unit on the substrate 1, i.e., the isolation member 20 has a signal shielding effect on the second touch unit.

The self-capacitive touch layer 8 includes touch units 81 of a grid-like structure. A plurality of touch units 81 are touch lines arranged in an array, and mutual capacitances are formed between the touch lines arranged in an array. When the finger approaches or touches the display panel 100, the values of the mutual capacitances change, and touch control is achieved by the changes in the respective mutual capacitances. The orthographic projection of the isolation member 20 on the substrate 1 at least partially overlaps with an orthographic projection of the touch line on the substrate 1, i.e., the isolation member 20 has a signal shielding effect on the touch line.

In some embodiments, the substrate 1 includes a base substrate 11 and a drive circuit layer 12. The drive circuit layer 12 is arranged between the base substrate 11 and the light-emitting device layer, and the drive circuit layer 12 includes a plurality of conductive structures. An orthographic projection of part of the conductive structure on the substrate 1 at least partially overlaps with the orthographic projection of the isolation member 20 on the substrate 1.

The conductive structure may specifically be a signal line for signal transmission in the drive circuit layer 12, a transistor 13 for driving the light-emitting unit 3 to emit light, etc. The orthographic projection of part of the conductive structure on the substrate 1 at least partially overlaps with the orthographic projection of the isolation member 20 on the substrate 1, and the isolation member 20 has a signal shielding effect on the part of the conductive structure.

In some embodiments, the isolation electrode 62 is insulated from the drive circuit layer 12, and the first electrode 61 is electrically connected to the drive circuit layer 12.

The first electrode 61 is electrically connected to the drive circuit layer 12 and the first electrode 61 can provide an electrical signal for the light-emitting unit 3 to drive the light-emitting unit 3 to emit light. The isolation electrode 62 is insulated from the drive circuit layer 12, and the circuit design in the display panel 100 is simplified.

In some embodiments, part of the encapsulation layer 7 fills the first opening 25 and is in contact with a surface of the isolation member 20 away from the substrate 1.

The part of the encapsulation layer 7 fills the first opening 25 to encapsulate and planarize the isolation structure 2, facilitating the provision of other functional layers on the side of the encapsulation layer 7 away from the substrate 1.

In some embodiments, the encapsulation layer 7 includes a first encapsulation sublayer 71. The first encapsulation sublayer 71 covers the side of the light-emitting device layer away from the substrate 1, the side of the isolation structure 2 away from the substrate 1 and a side of the isolation member 20 away from the substrate 1. Part of the first encapsulation sublayer 71 fills the first opening 25 and is in contact with the surface of the isolation member 20 away from the substrate 1.

The first encapsulation sublayer 71 encapsulates both the active area AA and the non-active area NA, thereby facilitating an improvement in the ability of the display panel 100 to resist water and oxygen.

In some embodiments, the display panel 100 further includes a second encapsulation sublayer 72. The second encapsulation layer 7 is arranged in the active area AA, and the second encapsulation sublayer 72 is located between the first encapsulation sublayer 71 and the light-emitting unit 3.

The second encapsulation sublayer 72 may be made of an organic material or an inorganic material. The first encapsulation sublayer 71 and the second encapsulation sublayer 72 may be made of the same material or of different materials. When the first encapsulation sublayer 71 and the second encapsulation sublayer 72 are made of different materials, the first encapsulation sublayer 71 and the second encapsulation sublayer 72 may have different properties to improve the ability of the display panel 100 to resist water and oxygen.

In some embodiments, the second encapsulation sublayer 72 includes a plurality of encapsulation portions 721 spaced apart from each other. An orthographic projection of the encapsulation portion 721 on the substrate 1 covers an orthographic projection of the light-emitting unit 3 on the substrate 1.

The encapsulation portions 721 and the light-emitting units 3 may be arranged in one-to-one correspondence. That is, one encapsulation portion 721 is used for encapsulating one light-emitting unit 3. The encapsulation portion 721 may be entirely arranged in the isolation opening 23, or may partially extend to the outside of the isolation opening 23. An edge of the encapsulation portion 721 is in lap joint with the isolation structure 2 to avoid or reduce the formation of a gap between the encapsulation portion 721 and the isolation structure 2 through which water and oxygen can pass.

In contrast to the second encapsulation sublayer 72 being distributed in the active area AA, the first encapsulation sublayer 71 is distributed in the active area AA and the non-active area NA.

In some embodiments, the first encapsulation sublayer 71 is an organic material layer, and the first planarization layer 51 is an organic material layer.

The organic material layer is more flexible than the inorganic material layer, and the first encapsulation sublayer 71 and the first planarization layer 51 have a planarization effect. The first encapsulation sublayer 71 and the first planarization layer 51 are also more likely to absorb water vapor, so the isolation member 20 is arranged between the first encapsulation sublayer 71 and the first planarization layer 51 to reduce the flow of the water vapor between the first encapsulation sublayer and the first planarization layer.

In some embodiments, the second encapsulation sublayer 72 is an inorganic material layer.

The inorganic material layer has a better water and oxygen blocking capability than the organic material layer, but the organic material layer has a better flexibility and a better film-forming property than the inorganic material layer. The light-emitting device layer is encapsulated by both the organic material layer and the inorganic material layer to improve the comprehensive ability of the display panel 100 to resist water and oxygen.

In some embodiments, the encapsulation layer 7 further includes a third encapsulation sublayer 73. The third encapsulation sublayer 73 is arranged on a side of the first encapsulation sublayer 71 away from the substrate 1.

The third encapsulation sublayer 73 may be made of an organic or inorganic material. The first encapsulation sublayer 71, the second encapsulation sublayer 72 and the third encapsulation sublayer 73 may be made of the same material or of different materials. The third encapsulation sublayer 73 facilitates an improvement in the ability of the display panel 100 to isolate the light-emitting device layer from water and oxygen. When the third encapsulation sublayer 73 and the first encapsulation sublayer 71 are made of different materials, the third encapsulation sublayer 73 and the first encapsulation sublayer 71 may have different properties to improve the ability of the display panel 100 to resist water and oxygen.

In some embodiments, the third encapsulation sublayer 73 is an inorganic material layer.

The material of the third encapsulation sublayer 73 may be the same as the material of the first encapsulation sublayer 71 to simplify the preparation process.

In some embodiments, the display panel 100 further includes a first conductive layer including a first signal line 15 located in the non-active area NA, the first planarization layer 51 has at least one third opening 511, and part of the isolation structure 2 is located in the third opening 511 and electrically connected to the first signal line 15.

The first signal line 15 may be arranged around the active area AA. The first signal line 15, the first planarization layer 51 and the isolation member 20 may be formed in sequence. Part of an isolation material for preparing the isolation structure 2 falls into the third opening 511, and this part of the isolating material is in contact with the first signal line 15 exposed from the third opening 511, thereby making the isolation structure 2 electrically connected to the first signal line 15, and the isolation structure 2 can be used to transmit an electrical signal.

In some embodiments, the orthographic projection of the isolation member 20 on the substrate 1 is located within the orthographic projection of the first signal line 15 on the substrate 1 and the isolation member 20 can shield the electrical signal of the first signal line 15, to reduce interference between the first signal line 15 and an electrical signal transmission structure located on a side of the isolation member 20 away from the substrate 1. The electrical signal transmission structure located on the side of the isolation member 20 away from the substrate 1 may be a touch signal line 82 (trace) electrically connected to the touch unit 81.

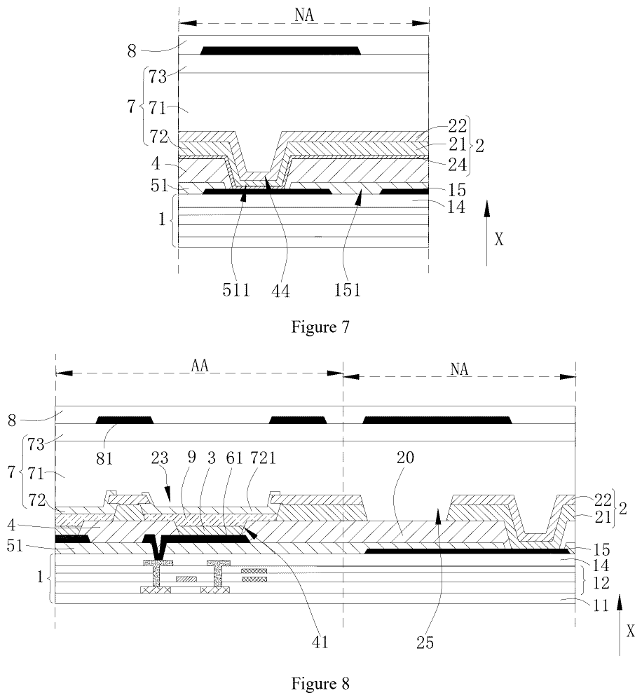

Referring to FIGS. 5, 6 and 7 together, in some embodiments, an orthographic projection of the third opening 511 on the substrate 1 is spaced apart from the orthographic projection of the first opening 25 on the substrate 1.

The pixel defining layer 4 may extend into the third opening 511, the pixel defining layer 4 has a fifth opening 44 located in the third opening 511, and the first signal line 15 is exposed from the fifth opening 44. The pixel defining layer 4 extends along a wall surface of the third opening 511 and water vapor in the first planarization layer 51 cannot be discharged through the third opening 511, and the second opening 42 is provided on the pixel defining layer 4 and the water vapor in the first planarization layer 51 can be discharged through the second opening 42. The third opening 511 and the second opening 42 are spaced apart from each other. The third opening 511 and the fifth opening 44 may be arranged coaxially.

In some embodiments, the display panel 100 further includes a second planarization layer 14. The second planarization layer 14 is located on a side of the first conductive layer close to substrate 1.

The second planarization layer 14 may be prepared first, to planarize a functional layer located on a side of the second planarization layer 14 close to the base substrate 11, thereby facilitating the preparation of the first conductive layer on the second planarization layer 14.

In some embodiments, the first conductive layer further includes at least one fourth opening 151 extending through the first signal line 15 along a thickness direction, and the first planarization layer 51 is in contact with the second planarization layer 14 via the fourth opening 151.

Water vapor in the second planarization layer 14 may be discharged outwardly through the fourth opening 151, and may also be moved into the first planarization layer 51 through the fourth opening 151 and then discharged through the second opening 42.

In some embodiments, an orthographic projection of the second opening 42 on the substrate 1 is spaced apart from an orthographic projection of the fourth opening 151 on the substrate 1, thereby avoiding interference between a conductive structure located on a side of the fourth opening 151 close to the base substrate 11 and an electrical signal transmission structure located on a side of the second opening 42 away from the base substrate 11.

In some embodiments, orthographic projections of a plurality of second openings 42 on the substrate 1 and orthographic projections of a plurality of third openings 511 on the substrate 1 are alternately spaced apart from each other in a first direction Y; and the orthographic projections of the plurality of third openings 511 on the substrate 1 and a plurality of fourth openings 151 are alternately spaced apart from each other in the first direction Y.

The provision of the plurality of second openings 42 and the plurality of third openings 511 facilitates the discharge of water vapor from the first planarization layer 51 and the second planarization layer 14, and the regular arrangement of the plurality of second openings 42 and the plurality of third openings 511 avoid or reduce the accumulation of water vapor in partial regions of the first planarization layer 51 and the second planarization layer 14 that cannot be effectively discharged. In one embodiment, a plurality of second openings 42 and a plurality of third openings 511 arranged in rows, and a plurality of fourth openings 151 and a plurality of third openings 511 arranged in rows may be arranged spaced apart from each other in a second direction Z. The first direction Y is perpendicular to the second direction Z.

In some embodiments, the display panel 100 further includes a second electrode layer including a plurality of second electrodes 9. The second electrodes 9 are arranged on a side of the light-emitting unit 3 away from the substrate 1. The second electrode 9 is in lap joint with the isolation structure 2.

One of the first electrode 61 and the second electrode 9 may be a cathode and the other may be an anode. The first electrode 61 and the second electrode 9 are connected to the light-emitting unit 3 and used to drive the light-emitting unit 3 to emit light. The encapsulation portion 721 may cover the side of the second electrode 9 away from the substrate 1, and the encapsulation portion 721 can reduce or avoid water and oxygen entering the light-emitting units 3, thereby prolonging the service life of the light-emitting units 3. In one embodiment, the first electrode 61 is an anode, and the second electrode 9 is a cathode.

In some embodiments, the second electrode 9 is electrically connected to the isolation structure 2.

An edge of the second electrode 9 is in lap joint with the first isolation layer 21, and the first isolation layer 21 can supply power to the second electrode 9, and also enable adjacent second electrodes 9 to conduct electricity, to form a surface electrode with the entire surface being electrically conductive.

Referring to FIG. 8, in some embodiments, the display panel 100 further includes a pixel defining layer 4. The pixel defining layer 4 is arranged between the first planarization layer 51 and the isolation structure 2, and the pixel defining layer 4 includes a pixel opening 41. The pixel opening 41 is in communication with the isolation opening 23, the light-emitting unit 3 is at least partially arranged in the pixel opening 41, and part of the pixel defining layer 4 doubles as the isolation member.

The pixel defining layer 4 extending to the non-active area NA doubles as the isolation member 20 to be spaced between the first planarization layer 51 and the encapsulation layer 7, thereby preventing an agent used in a process after the preparation of the pixel defining layer 4 from entering the first planarization layer 51.

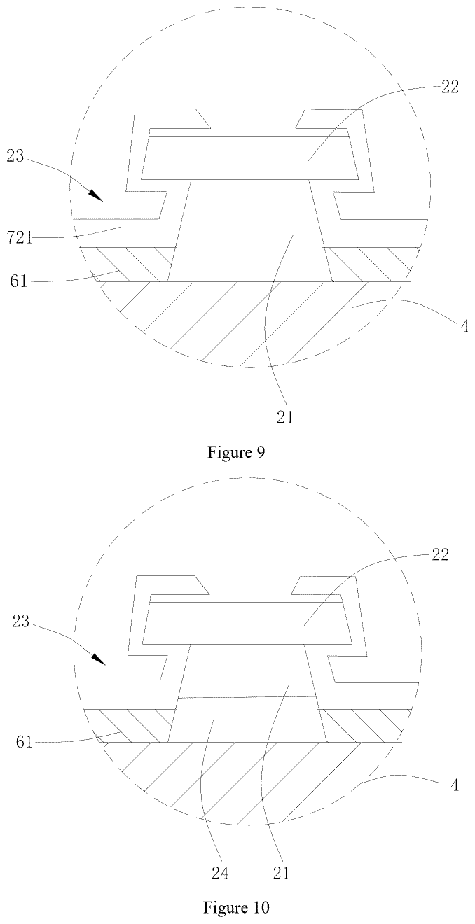

Referring to FIGS. 5 and 9, in some embodiments, the isolation structure 2 includes a first isolation layer 21 and a second isolation layer 22 arranged in a stacked manner. The first isolation layer 21 is arranged on a side of the second isolation layer 22 close to the substrate 1, and an orthographic projection of the first isolation layer 21 on the substrate 1 is located within an orthographic projection of the second isolation layer 22 on the substrate 1.

The isolation structure 2 encloses the isolation opening 23, to limit the arrangement range of the light-emitting device layer. The isolation structure 2 includes a first isolation layer 21 and a second isolation layer 22 that are arranged in a stacked manner, and an orthographic projection of the first isolation layer 21 on the substrate 1 is located within an orthographic projection of the second isolation layer 22 on the substrate 1, and an end of the isolation structure 2 away from the substrate 1 has a larger cross-sectional area than an end of the isolation structure 2 close to the substrate 1. In a direction from the isolation structure 2 to the substrate 1, the second isolation layer 22 shields the entire first isolation layer 21.

When the light-emitting units 3 are prepared, a light-emitting material A used for preparing the light-emitting units 3 may cover the isolation structure 2 by means of evaporation technology. Since the second isolation layer 22 shields the first isolation layer 21, the light-emitting material A used for preparing the light-emitting units 3 has a large drop at an edge of the second isolation layer 22, and it is unlikely to connect the light-emitting material A falling into the isolation opening 23 and the light-emitting material A falling on the second isolation layer 22. Accordingly, breakage occurs, and pieces of light-emitting material A spaced apart from each other are formed in adjacent isolation openings 23. Compared with the prior art that a light-emitting device layer is prepared by means of mask evaporation, in the disclosure, by providing the first isolation layer 21 and the second isolation layer 22, the light-emitting units 3 in the isolation openings 23 can be prepared without using a metal mask, and the cost of preparing the metal mask is omitted. Compared with the light-emitting device layer prepared by preparing a high-precision metal mask for evaporation, it is easier to directly prepare a high-precision isolation structure 2, and the structure of the display panel 100 provided by the disclosure has low requirements for a preparation process, and the prepared display panel 100 has good consistency. The light-emitting material A may be a complex containing an indium element.

In some embodiments, the orthographic projection of the isolation member 20 on the substrate 1 partially overlaps with the orthographic projection of the isolation structure 2 on the substrate 1.

The isolation member 20 and the first isolation layer 21 each have a function of shielding signals on two sides, and the orthographic projection of the isolation member 20 on the substrate 1 partially overlaps with an orthographic projection of the first isolation layer 21 on the substrate 1 to increase the area where the two together can shield signals.

In some embodiments, the orthographic projection of the first isolation layer 21 on the substrate 1 surrounds and overlaps with the orthographic projection of the isolation member 20 on the substrate 1 and there is no gap between the orthographic projection of the first isolation layer 21 on the substrate 1 and the orthographic projection of the isolation member 20 on the substrate 1, to form a full-surface projection, thereby increasing the area where the two together can shield signals.

In some embodiments, the area of an orthographic projection of a surface, away from the substrate 1, of the second isolation layer 22 on the substrate 1 is less than the area of an orthographic projection of a surface, close to the substrate 1, of the second isolation layer 22 on the substrate 1.

The second isolation layer 22 extends outwardly relative to the first isolation layer 21 by a predetermined distance, that is, the area of the orthographic projection of the surface, away from the substrate 1, of the second isolation layer 22 on the substrate 1 is less than the area of the orthographic projection of the surface, close to the substrate 1, of the second isolation layer 22 on the substrate 1, and the second isolation layer 22 has an inclined ramp structure, to define a pattern of the light-emitting unit 3 by means of the second isolation layer 22.

In some embodiments, the cross-sectional area of the second isolation layer 22 gradually decreases in a direction away from the substrate 1.

In one embodiment, the cross-section of the second isolation layer 22 is in the shape of a trapezoid with a bottom base facing the substrate 1, and the second isolation layer 22 has a ramp surface, facilitating the breakage of a preparation material at a partition edge, allowing part of the preparation material to be located on the second isolation layer 22 and part of the preparation material to be located in the isolation opening.

In some embodiments, the area of an orthographic projection of a surface, away from the substrate 1, of the first isolation layer 21 on the substrate 1 is less than the area of the orthographic projection of the surface, close to the substrate 1, of the second isolation layer 22 on the substrate 1.

That is, the second isolation layer 22 extends outwardly relative to the first isolation layer 21 to limit the pattern of the light-emitting unit 3 by means of the second isolation layer 22. The second isolation layer 22 has a greater area than the first isolation layer 21 and covers the entire first isolation layer 21. In this case, the first isolation layer 21 is recessed relative to the second isolation layer 22 in a direction away from the isolation opening. When the light-emitting units 3 are prepared, at least part of the material used for preparing the light-emitting units 3 has a large drop at an edge of the isolation structure 2, and the first isolation layer 21 is recessed, and the material used for preparing the light-emitting units 3 are unlikely to be continuous on an outer side of the isolation structure 2, and accordingly breakage occurs, to form the light-emitting units 3 which are isolated from each other.

In one embodiment, the isolation structure 2 is in the form of a grid, and the isolation openings are arranged in an array to improve the light emission uniformity of the light-emitting units 3 provided.

Referring to FIGS. 5 and 10, in some embodiments, the isolation structure 2 further includes a third isolation layer 24. The third isolation layer 24 is arranged on a side of the first isolation layer 21 close to the substrate 1, and the orthographic projection of the first isolation layer 21 on the substrate 1 is located within an orthographic projection of the third isolation layer 24 on the substrate 1.

In the active area AA, the isolation structure 2 may have an I-shaped cross-section. In one embodiment, the area of the orthographic projection of the first isolation layer 21 on the substrate 1 is less than the area of the orthographic projection of the third isolation layer 24 on the substrate 1.

The first isolation layer 21 may have a trapezoidal cross-section to increase the size of the isolation opening 23. The cross-section of the first isolation layer 21 may be in the shape of a right trapezoid, and the second isolation layer 22 can be securely supported, and the first isolation layer 21 and the second isolation layer 22 have a small contact surface area. The orthographic projection of the first isolation layer 21 on the substrate 1 is located within the orthographic projection of the third isolation layer 24 on the substrate 1, and the third isolation layer 24 can stably support the first isolation layer 21, thereby achieving the recessed configuration of the first isolation layer 21 with respect to the second isolation layer 22 in a direction away from the central axis of the isolation opening 23, and facilitating the breakage of the light-emitting device layer at the isolation structure 2. Etching waste produced by etching the first isolation layer 21 falls on the third isolation layer 24 to facilitate cleaning.

In some other embodiments, the second electrode 9 is electrically connected to the third isolation layer 24. In one embodiment, a material of the third isolation layer 24 includes molybdenum metal; and/or a material of the first isolation layer 21 includes aluminum metal; and/or a material of the second isolation layer 22 includes titanium metal.

In some embodiments, an orthographic projection of the pixel opening 41 on the substrate 1 is located within the range of an orthographic projection of the isolation opening 23 on the substrate 1.

The area of the isolation opening 23 is larger than the area of the pixel opening 41, and the influence of the isolation structure 2 on a light output viewing angle of the light-emitting device layer can be reduced.

In an embodiment, a plurality of pixel openings 41 are provided. The plurality of pixel openings 41 are distributed at intervals, and the isolation structure 2 may be arranged on at least part of a pixel defining portion between two adjacent pixel openings 41. In one embodiment, the isolation structure 2 may surround at least part of the pixel opening 41.

An embodiment of a second aspect of the disclosure provides a display panel 100. The display panel 100 has an active area AA and a non-active area NA. The non-active area NA is arranged around at least part of the active area AA. The display panel 100 includes: a substrate 1, a first planarization layer 51, a pixel defining layer 4, a light-emitting device layer, an encapsulation layer 7 and an isolation member 20. The first planarization layer 51 is arranged on one side of the substrate 1. The pixel defining layer 4 is located on a side of the first planarization layer 51 away from the substrate 1, and the pixel defining layer 4 has a plurality of pixel openings 41 and at least one second opening 42. The pixel openings 41 are located in the active area AA, and the second opening 42 is located in the non-active area NA. At least part of an orthographic projection of the second opening 42 on the substrate 1 is located within an orthographic projection of the first planarization layer 51 on the substrate 1. The light-emitting device layer includes a plurality of light-emitting units 3 located in the active area AA. At least part of the light-emitting unit 3 is arranged in the pixel opening 41, and the light-emitting unit 3 includes an organic electroluminescent material. The encapsulation layer 7 is located on a side of the pixel defining layer 4 away from the substrate 1 and covers at least part of the second opening 42. The isolation member 20 is located in the non-active area NA, the orthographic projection of the isolation member 20 on the substrate 1 at least partially overlaps with the orthographic projection of the second opening 42 on the substrate 1, and the isolation member 20 separates the first planarization layer 51 from the encapsulation layer 7.

In the display panel 100 provided by the disclosure, by providing the second opening 42 in the pixel defining layer 4, the water vapor in the first planarization layer 51 can be discharged outwardly through the second opening 42 during the preparation of the display panel 100; the arrangement of the second opening 42 in the non-active area NA facilitates an increase in the distribution density of the light-emitting units 3 in the active area AA; and by configuring the orthographic projection of the isolation member 20 on the substrate 1 to at least partially overlap with the orthographic projection of the second opening 42 on the substrate 1 and the isolation member 20 to separate the first planarization layer 51 from the encapsulation layer 7, the isolation member 20 can isolate the first planarization layer 51 from the encapsulation layer 7 to avoid contact between the first planarization layer 51 and the encapsulation layer 7, thereby avoiding or reducing the absorption of a liquid agent during the preparation of the first planarization layer 51, avoiding or reducing the water vapor in the first planarization layer 51 entering the encapsulation layer 7 through the second opening 42, prolonging the service life of the light-emitting units 3, and avoiding or reducing display abnormalities of the light-emitting units 3.

An embodiment of a third aspect of the disclosure provides a preparation method for a display panel. The display panel 100 has an active area AA and a non-active area NA. The non-active area NA is arranged around at least part of the active area AA. The preparation method includes:
S100, providing a substrate 1, a first planarization layer 51 being provided on the substrate 1;
S200, forming a first electrode layer 6 on the first planarization layer 51, the first electrode layer 6 including a plurality of first electrodes 61 located in the active area AA and an isolation electrode 62 located in the non-active area NA, the isolation electrode 62 doubling as an isolation member 20;
S300, forming an isolation structure 2 on a side of the first electrode layer 6 away from the substrate 1, the isolation structure 2 having a plurality of isolation openings 23 and at least one first opening 25, the isolation openings 23 being located in the active area AA, the first opening 25 being located in the non-active area NA, and an orthographic projection of the first opening 25 on the substrate 1 at least partially overlapping with an orthographic projection of the isolation electrode 62 on the substrate 1;
S500, providing part of a light-emitting device layer by means of the isolation structure 2, the light-emitting device layer including a plurality of light-emitting units 3 located in the active area AA, at least part of the light-emitting unit 3 being arranged in the isolation opening 23; and
S600, forming an encapsulation layer 7 on a side of the isolation structure 2 away from the substrate 1, and the isolation member 20 separating the first planarization layer 51 from the encapsulation layer 7.

S300 may further include:
providing a pixel defining material layer and an isolation material layer on the first planarization layer 51, the pixel defining material layer covering the first electrode 61, patterning the pixel defining material layer and the isolation material layer to obtain a second opening 42 located in the non-active area NA and a pixel opening 41 located in the active area AA, communicating the isolation opening 23 with the pixel opening 41, and communicating the second opening 42 with the first opening 25.

The pixel defining material layer is used to prepare the pixel defining layer 4. The isolation material layer and the pixel defining material layer can be patterned by wet and dry etching processes to obtain the required isolation structure 2 and pixel defining layer 4. After S200, the preparation method may include: performing a drying treatment on the first planarization layer 51 and water vapor in the first planarization layer 51 is discharged from the second opening 42. The drying treatment may alternatively be performed on first planarization layer 51 by using the ambient temperature required to prepare the first electrode layer 6.

An etching solution used in forming the isolation structure 2, the excess light-emitting material removed during the preparation of the light-emitting units 3, and an agent used in a photoresist are all blocked by the isolation member 20, thereby preventing the agent from entering the first planarization layer 51, thus avoiding or reducing the water vapor entering the encapsulation layer 7 and the light-emitting units 3 in sequence from the first planarization layer 51 in the prepared display panel 100, and prolonging the service life of the light-emitting units 3.

In S500, when preparing the other parts of the light-emitting units 3 except the first electrode 61, the light-emitting units 3 of different colors may be prepared in steps. For example, a first light-emitting material is evaporated by an evaporation process, the light-emitting material located in a first isolation opening 23 is retained to form a first light-emitting unit 3 for emitting light of a first color, and the light-emitting material in the other isolation openings 23 is removed; a second light-emitting material is then evaporated by an evaporation process, the light-emitting material in the second isolation opening 23 is retained to form the first light-emitting unit for emitting light of a second color, and the light-emitting material in the other isolation openings 23 is removed, and so on, until the light-emitting units 3 of the desired types are prepared.

In some embodiments, S200 includes:
providing a first electrode material layer on the first planarization layer 51; and etching a first conductive material layer using a first mask to form a first electrode 61 and an isolation electrode 62.

The first electrode 61 and the isolation electrode 62 are obtained together by the same etching step.

In some embodiments, after S200, the preparation method includes:
S201, performing an annealing treatment on the first electrode layer 6.

The annealing treatment on the first electrode layer 6 can improve the corrosion resistance of surfaces of the first electrode 61 and the isolation electrode 62 and improve the properties of the material. When performing the annealing treatment on the first electrode layer 6, the high temperature can also cause the water vapor in the first planarization layer 51 to be discharged from the second opening 42, facilitating the drying of the first planarization layer 51. The drying treatment may alternatively be performed on the first planarization layer 51 by using the ambient temperature required to treat the first electrode layer 6.

The etching solution used in forming the isolation structure 2, the excess light-emitting material removed during the preparation of the light-emitting units 3, and the agent used in a photoresist are all blocked by the isolation member 20, thereby preventing the agent from entering the first planarization layer 51, thus avoiding or reducing the water vapor entering the encapsulation layer 7 and the light-emitting units 3 in sequence from the first planarization layer 51 in the prepared display panel 100, and prolonging the service life of the light-emitting units 3.

In some embodiments, in the annealing treatment, the annealing temperature ranges from 200° C. to 240° C. and the annealing time ranges from 30 min to 70 min. In one embodiment, the annealing temperature is 200° C., 210° C., 220° C., 230° C., etc., and the annealing time is 30 min, 40 min, 50 min, 60 min, 70 min.

An embodiment of a fourth aspect of the disclosure further provides a display device. Referring to FIGS. 1 and 2, the display device includes a display panel 100 according to any one of the above embodiments of the first aspect, or a display panel 100 prepared by any one of the above embodiments of the second and third aspects. Since the display device according to the embodiment of the fourth aspect of the disclosure includes the display panel 100 according to any one of the above embodiments of the first aspect, or the display panel 100 prepared by any one of the above embodiments of the second and third aspects, the display device according to the embodiment of the third aspect of the disclosure has the beneficial effects of the display panel 100 according to any one of the above embodiments of the first aspect, or the display panel 100 prepared by any one of the above embodiments of the second and third aspects, which will not be described in detail here.

The display device in the embodiment of the disclosure includes, but is not limited to devices having a display function, such as a cell phone, a personal digital assistant (PDA), a tablet computer, an e-book, a television, an access control, a smart fixed-line telephone, or a control console.

The embodiments of the disclosure as described above neither set forth all the details, nor do they limit the disclosure to only the described embodiments. Apparently, many modifications and variations can be made in light of the above description. The embodiments are selected and described in this specification to better explain the principles and practical applications of the disclosure, and good use of the disclosure and modify and use the disclosure. The disclosure is limited only by the claims and all the scopes and equivalents thereof.

1. A display panel, having an active area and a non-active area, the non-active area being arranged around at least part of the active area, the display panel comprising:
a substrate;
a first planarization layer arranged on one side of the substrate;
an isolation structure, located on a side of the first planarization layer away from the substrate, the isolation structure having a plurality of isolation openings located in the active area and at least one first opening, located in the non-active area, at least part of an orthographic projection of the first opening on the substrate being located within an orthographic projection of the first planarization layer on the substrate;
a light-emitting device layer, comprising a plurality of light-emitting units located in the active area, at least part of the light-emitting unit being arranged in the isolation opening, and the light-emitting unit comprising an organic electroluminescent material; an encapsulation layer, located on a side of the isolation structure away from the substrate and covering at least part of the first opening; and
an isolation member, located in the non-active area, and separating the first planarization layer from the encapsulation layer, an orthographic projection of the isolation member on the substrate at least partially overlapping with the orthographic projection of the first opening on the substrate.

2. The display panel according to claim 1, wherein the isolation member comprises an inorganic material;
the display panel further comprises a first electrode layer, the first electrode layer comprising a plurality of first electrodes and at least one isolation electrode, the first electrode being arranged on a side of the light-emitting unit close to the substrate, an orthographic projection of the first electrode on the substrate at least partially overlapping with an orthographic projection of the isolation opening on the substrate, and the isolation electrode doubling as the isolation member.

3. The display panel according to claim 2, further comprising
a pixel defining layer arranged between the substrate and the isolation structure, the pixel defining layer comprising a pixel opening and a second opening, the pixel opening being in communication with the isolation opening, the light-emitting unit being at least partially arranged in the pixel opening, and the second opening being in communication with the first opening;
an orthographic projection of the second opening on the substrate being located within the orthographic projection of the first opening on the substrate;
the isolation member comprising a first surface and a second surface arranged opposite to each other, and a side surface connected to the first surface, the first surface being arranged on a side of the second surface away from the substrate, and the pixel defining layer cladding at least part of the side surface; and
the pixel defining layer covering part of the first surface.

4. The display panel according to claim 3, wherein the plurality of first electrodes and the at least one isolation electrode are spaced apart from each other;
part of the pixel defining layer is located between an adjacent one of the first electrodes and the isolation electrode; and
the pixel defining layer surrounds the isolation electrode.

5. The display panel according to claim 3, wherein the at least one isolation electrode is connected to the first electrode; and
the first electrode comprises a third surface in contact with the light-emitting unit, the pixel defining layer covers part of the third surface, and the first surface and the third surface are connected to form a flat surface.

6. The display panel according to claim 3, further comprising a touch layer located on a side of the encapsulation layer away from the substrate, the touch layer comprising a plurality of touch units, an orthographic projection of the touch unit on the substrate at least partially overlapping with the orthographic projection of the isolation member on the substrate.

7. The display panel according to claim 3, the substrate comprises a base substrate and a drive circuit layer arranged between the base substrate and the light-emitting device layer, the drive circuit layer comprising a plurality of conductive structures, an orthographic projection of part of the conductive structures on the substrate at least partially overlapping with the orthographic projection of the isolation member on the substrate;
the isolation electrode being insulated from the drive circuit layer, and the first electrode being electrically connected to the drive circuit layer.

8. The display panel according to claim 1, wherein part of the encapsulation layer fills the first opening and is in contact with a surface of the isolation member away from the substrate;
the encapsulation layer comprising a first encapsulation sublayer covering a side of the light-emitting device layer away from the substrate and the side of the isolation structure away from the substrate, part of the first encapsulation sublayer filling the first opening and being in contact with the surface of the isolation member away from the substrate;
the encapsulation layer further comprising a second encapsulation sublayer arranged in the active area, the second encapsulation sublayer being located between the first encapsulation sublayer and the light-emitting unit;
the second encapsulation sublayer comprising a plurality of encapsulation portions spaced apart from each other, an orthographic projection of the encapsulation portion on the substrate covering an orthographic projection of the light-emitting unit on the substrate;
the first encapsulation sublayer being an organic encapsulation layer, and the first planarization layer being an organic encapsulation layer; and
the second encapsulation sublayer being an inorganic material layer.

9. The display panel according to claim 1, further comprising a first conductive layer comprising a first signal line located in the non-active area, the first planarization layer has at least one third opening, and part of the isolation structure is located in the third opening and electrically connected to the first signal line;
the orthographic projection of the isolation member on the substrate being located within an orthographic projection of the first signal line on the substrate; and an orthographic projection of the third opening on the substrate being spaced apart from the orthographic projection of the first opening on the substrate.

10. The display panel according to claim 9, further comprising a second planarization layer located on a side of the first conductive layer close to the substrate;
the first conductive layer further comprising at least one fourth opening extending through the first signal line, and the first planarization layer being in contact with the second planarization layer via the fourth opening.

11. The display panel according to claim 10, the orthographic projection of the first opening on the substrate is spaced apart from an orthographic projection of the fourth opening on the substrate;
the at least one first opening comprises a plurality of first openings, the at least one third opening comprises a plurality of third openings, the at least one fourth opening comprises a plurality of fourth openings, orthographic projections of the plurality of first openings on the substrate and orthographic projections of the plurality of third openings on the substrate are alternately spaced apart from each other in a first direction; and the orthographic projections of the plurality of third openings on the substrate and the plurality of fourth openings are alternately spaced apart from each other in the first direction.

12. The display panel according to claim 2, wherein further comprising a second electrode layer, the second electrode layer comprising a plurality of second electrodes arranged on a side of the light-emitting unit away from the substrate, the second electrode being in lap joint with the isolation structure, and the second electrode being electrically connected to the isolation structure.

13. The display panel according to claim 1, wherein the isolation structure comprises a first isolation layer and a second isolation layer arranged in a stacked manner, the first isolation layer being arranged on a side of the second isolation layer close to the substrate, and an orthographic projection of the first isolation layer on the substrate being located within an orthographic projection of the second isolation layer on the substrate; and
the orthographic projection of the isolation member on the substrate at least partially overlapping with an orthographic projection of the isolation structure on the substrate.

14. The display panel according to claim 13, wherein an area of an orthographic projection of a surface, away from the substrate, of a second isolation layer on the substrate, is less than an area of an orthographic projection of a surface, close to the substrate, of the second isolation layer on the substrate.

15. The display panel according to claim 13, wherein
an area of an orthographic projection of a surface, away from the substrate, of a first isolation layer on the substrate is less than an area of an orthographic projection of a surface, close to the substrate, of a second isolation layer on the substrate.

16. A display panel, having an active area and a non-active area, the non-active area being arranged around at least part of the active area, the display panel comprising:
a substrate;
a first planarization layer, arranged on one side of the substrate;
a pixel defining layer, located on a side of the first planarization layer away from the substrate, the pixel defining layer comprising a plurality of pixel openings located in the active area and at least one second opening located in the non-active area, at least part of an orthographic projection of the second opening on the substrate being located within an orthographic projection of the first planarization layer on the substrate;
a light-emitting device layer, comprising a plurality of light-emitting units located in the active area, at least part of the light-emitting unit being arranged in the pixel opening, and the light-emitting unit comprising an organic electroluminescent material;
an encapsulation layer, located on a side of the pixel defining layer away from the substrate and covering at least part of the second opening; and
an isolation member, located in the non-active area and separating the first planarization layer from the encapsulation layer, an orthographic projection of the isolation member on the substrate at least partially overlapping with the orthographic projection of the second opening on the substrate.

17. A preparation method for a display panel, the display panel having an active area and a non-active area, the non-active area being arranged around at least part of the active area, the preparation method comprising:
providing a substrate on which a first planarization layer is provided;
forming a first electrode layer on the first planarization layer, the first electrode layer comprising a plurality of first electrodes located in the active area and an isolation electrode located in the non-active area, the isolation electrode doubling as an isolation member;
forming an isolation structure on a side of the first electrode layer away from the substrate, the isolation structure having a plurality of isolation openings located in the active area and at least one first opening located in the non-active area, an orthographic projection of the first opening on the substrate at least partially overlapping with an orthographic projection of the isolation electrode on the substrate;
providing a light-emitting device layer by means of the isolation structure, the light-emitting device layer comprising a plurality of light-emitting units located in the active area, at least part of the light-emitting unit being arranged in the isolation opening; and
forming an encapsulation layer on a side of the isolation structure away from the substrate, and the isolation member separating the first planarization layer from the encapsulation layer.

18. The preparation method for a display panel according to claim 17, after forming a first electrode layer on the first planarization layer, comprising:
performing an annealing treatment on the first electrode layer;
in the annealing treatment, the annealing temperature ranges from 200° C. to 240° C. and the annealing time ranges from 30 min to 70 min.
